(19) United States
(12) Patent Application Publication
(10) Pub. No.: US 2024/0014619 A1
(43) Pub. Date: Jan. 11, 2024

(54) TECHNIQUES FOR AUTOMATICALLY DEPOSITING ELECTRICAL WIRING

(71) Applicant: Xaba Inc., Toronto (CA)

(72) Inventors: Francesco IORIO, Toronto (CA); Massimiliano MORUZZI, Rockford, IL (US)

(21) Appl. No.: 18/348,186

(22) Filed: Jul. 6, 2023

Related U.S. Application Data
(60) Provisional application No. 63/359,178, filed on Jul. 7, 2022.

(51) Int. Cl. H01R 43/20; H01L 31/18

(52) U.S. Cl. CPC H01R 43/205; H01L 31/188

(57) ABSTRACT

An apparatus includes: at least one conductive wire spool; a motion platform that includes a first actuator for following a first programmed motion in a first dimension and a second actuator for following a second programmed motion in a second dimension that is perpendicular to the first direction; a deposition head that is mounted to the motion platform, receives a conductive wire from the conductive wire spool, and attaches the conductive wire onto a surface of a substrate; and a controller that causes the motion platform to move along a programmed deposition path on the surface of the substrate, wherein at least a portion of the programmed deposition path varies in the first dimension and in the second dimension.

### CROSS-REFERENCE TO RELATED APPLICATIONS

This application claims priority benefit of the United States Provisional Patent Application titled, “TECHNIQUES FOR AUTOMATICALLY DEPOSITING ELECTRICAL WIRING” filed on Jul. 7, 2022, and having Ser. No. 63/359,178. The subject matter of this related application is hereby incorporated herein by reference.

### BACKGROUND

### Field of the Various Embodiments

The various embodiments relate generally to automated manufacturing and, more specifically, to techniques for automatically depositing electrical wiring.

### DESCRIPTION OF THE RELATED ART

Products that contain electronic components usually include various and complex wiring systems to transport power and control signals between different subsystems within the products. When such a product is large in size, routing and reliably connecting power and control signals within these types of wiring systems can become a significant challenge when fabricating the product.

For example, manufacturing a photovoltaic (PV) solar panel requires fabricating a complex and delicate wiring system to create an electrical circuit connecting all of the different solar cells included within the PV solar panel. In addition, the solar cells may be distributed in an irregular layout on or within the panel, requiring complicated and difficult-to-connect wiring patterns. Because PV solar panels oftentimes include arrays of individual solar cells that are wired together in series, a single poor connection between any two solar cells in an array can prevent the entire array from generating electrical power.

As a further complicating factor, the actual electrical performance of a given solar cell is highly dependent on how the conductors for collecting charge are arranged on the surface of the solar cell. When these types of conductors are more numerous and closely spaced, electrons travel a shorter distance within the solar cell before being collected, which reduces resistive losses. In addition, when these types of conductors are larger, the electrical connections between the conductors or between the conductors and other elements are generally more reliable and less susceptible to failure. However, using larger and more numerous conductors for collecting charge from a solar cell has certain disadvantages. First, increasing the size of these types of conductors requires more resources, such as silver and other conductive materials. Second, when the size and number of conductors is increased, the conductors end up covering more of the surface area of a solar cell, which can cause the conductors to shade a substantial amount of solar cell surface area from incident solar radiation, thereby reducing the overall efficiency of the solar cell.

One approach to addressing the above problems is to replace conventional busbars and ribbons on solar cells with SmartWire Connection Technology (SWCT®). SWCT® is an interconnection technology for solar cells that implements copper wires that are coated with a thin low melting point alloy layer and supported by a polymer foil. Using SWCT® increases solar cell efficiency by lowering the ohmic losses associated with charge collection. In addition, SWCT® enables a grid that includes a large number of very narrow conductors to be fine-line printed on a solar cell, which reduces the amount of silver required for the solar cell as well as the amount of solar cell surface area shaded by the conductors. Further, having a larger number of conductors on each solar cell increases connection reliability because the operation of the solar cell is not dependent on only a few electrical ribbons or busbars.

One drawback to using SWCT®, however, is that the normal grid layout of conductors across the surface of a solar cell employed in SWCT® does not optimize charge collection from the solar cell. Given the electrical and electromagnetic properties of a typical solar cell, the optimal routings of conductors across the surface of a solar cell for charge collection oftentimes is curvilinear and, in some instances, multi-layered and/or multi-directional. These types of routings cannot be accommodated using the regular grid of parallel conductors employed in SWCT®; therefore, SWCT® oftentimes cannot provide optimal charge collection from a solar cell. Another drawback of using SWCT® is that many of the conductors included in a grid layout can be superfluous, which wastes silver and other conductive materials and results in needless shading of the solar cell.

As the foregoing illustrates, what is needed in the art are more effective techniques for wiring solar panels and other products that contain electronic components.

### SUMMARY

An apparatus includes: at least one conductive wire spool; a motion platform that includes a first actuator for following a first programmed motion in a first dimension and a second actuator for following a second programmed motion in a second dimension that is perpendicular to the first direction; a deposition head that is mounted to the motion platform, receives a conductive wire from the conductive wire spool, and attaches the conductive wire onto a surface of a substrate; and a controller that causes the motion platform to move along a programmed deposition path on the surface of the substrate, wherein at least a portion of the programmed deposition path varies in the first dimension and in the second dimension.

At least one technical advantage of the disclosed techniques relative to the prior art is that the disclosed techniques enable wiring or other conductors to be deposited on a two- or three-dimensional substrate, such as a photovoltaic solar cell, more precisely that what can be achieved using prior art approaches and in curvilinear fashion. As a result, conductors on the surface of a photovoltaic solar cell can be positioned in a more optimized configuration for charge collection relative to what can be achieved using prior art approaches. Among other things, the more optimized positioning of the conductors reduces ohmic losses and shading of the photovoltaic solar cell, thereby increasing the overall efficiency of the solar cell. In addition, less silver and/or other conductive materials is required for charge collection and interconnecting adjacent photovoltaic solar cells. These technical advantages provide one or more technological advancements over prior art approaches.

### BRIEF DESCRIPTION OF THE DRAWINGS

So that the manner in which the above recited features of the various embodiments can be understood in detail, a more particular description of the inventive concepts, briefly summarized above, may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.1

FIG. 1 illustrates a computer-controlled conductor deposition machine configured to implement one or more aspects of the various embodiments.

FIG. 2 schematically illustrates a photovoltaic solar cell, according to various embodiments.

FIG. 3 is a more detailed illustration of the deposition head in FIG. 1, according to various embodiments.

FIG. 4 is a more detailed illustration of the deposition head of FIG. 1, according to other various embodiments.

FIG. 5 is another more detailed illustration of a deposition head, according to various embodiments.

FIG. 6 sets forth a flowchart of method steps for depositing wire when manufacturing a wired product, according to various embodiments.

FIG. 7 schematically illustrates a multi-component substrate, according to various embodiments.

FIG. 8 schematically illustrates a film-wiring system, according to various embodiments.

FIG. 9 schematically illustrates an electronic device functionalization system, according to various embodiments.

FIG. 10 sets forth a flowchart of method steps for functionalizing an electronic component or electronic device with a wired conductive film, according to various embodiments.

For clarity, identical reference numbers have been used, where applicable, to designate identical elements that are common between figures. It is contemplated that features of one embodiment may be incorporated in other embodiments without further recitation.

### DETAILED DESCRIPTION

In the following description, numerous specific details are set forth to provide a more thorough understanding of the various embodiments. However, it will be apparent to one of skill in the art that the inventive concepts may be practiced without one or more of these specific details.

### System Overview

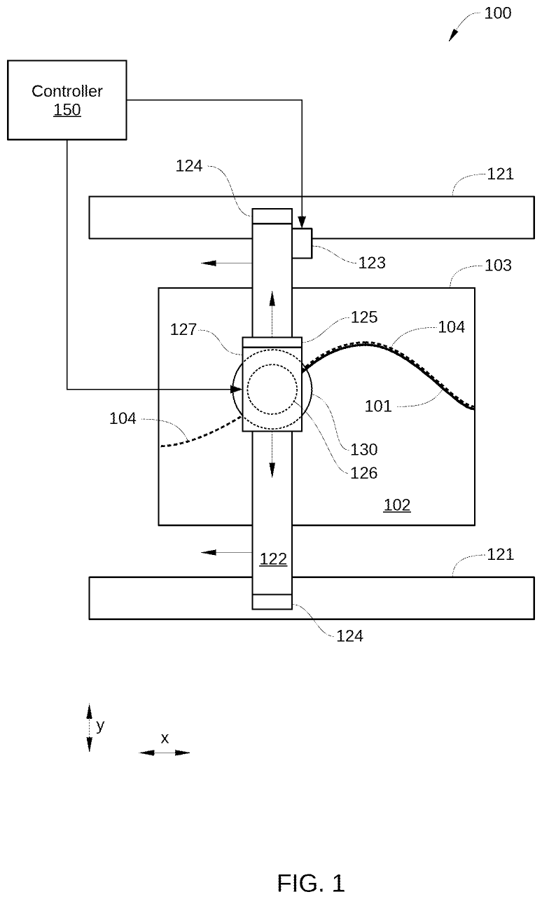

FIG. 1 illustrates a computer-controlled conductor-deposition machine 100 configured to implement one or more aspects of the various embodiments. Computer-controlled conductor-deposition machine 100 is a multi-axis computer-controlled processing machine that attaches or otherwise deposits one or more conductive wires 101 onto a surface 102 of a substrate 103. As shown, computer-controlled conductor-deposition machine 100 deposits the one or more conductive wires 101 along a programmed deposition path 104 (dashed line) on surface 102. According to various embodiments, at least a portion of programmed deposition path 104 varies in two or three dimensions, and therefore is not a straight line. In the embodiment illustrated in FIG. 1, programmed deposition path 104 varies in an x-direction and a y-direction. Alternatively or additionally, in some embodiments, programmed deposition path 104 can also vary in the z (into page) direction. In such embodiments, surface 102 is a non-planar, three-dimensional surface.

Substrate 103 can be any component or structure that is configured to have one or more conductors mounted thereto. For example, in some embodiments, substrate 103 is a photovoltaic (PV) solar cell or array of PV solar cells. In such embodiments, conductive wires 101 can act as charge collectors, and programmed deposition path 104 corresponds to an ideal location for one such charge collector. One embodiment of a PV solar cell with such conductive wires 101 is described below in conjunction with FIG. 1.

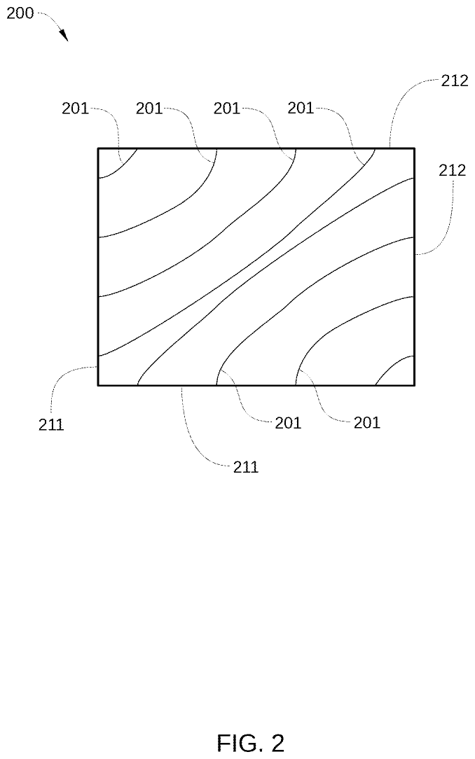

FIG. 2 schematically illustrates a PV solar cell 200, according to various embodiments. As shown, PV solar cell 200 includes a plurality of conductive wires 201 that are arranged for optimal or otherwise improved charge collection. Consequently, each conductive wire 201 follows a different curvilinear path across a surface 202 of PV solar cell 200. In addition, each conductive wire 201 is routed from one or more starting edges 211 of PV solar cell 200 to one or more ending edges 212 of PV solar cell 200. In some embodiments, charge is received, for example from an adjacent PV solar cell (not shown) along starting edges 211, and charge is collected from PV solar cell 200 along ending edges 212.

According to various embodiments, each curvilinear path across surface 202 of conductive wires 201 can be determined based a stochastic analysis or other estimate of current generation within PV solar cell 200. For example, in some embodiments, each curvilinear path followed by a conductive wire 202 corresponds to a streamline defining motion of charges generated within PV solar cell 200 when receiving incident light. As a result, the spacing and number of conductive wires 201 can be selected based on the trade-off between having a larger number of conductive wires 201, which increases shading and material use, and have a smaller number of conductive wires 201, which increases ohmic losses due to resistance within PV solar cell 200.

Returning to FIG. 1, computer-controlled conductor-deposition machine 100 includes a pair of runway beams 121, a bridge girder 122, a deposition head 130, and a controller 150. Runway beams 121 support bridge girder 122, and enable bridge girder 122 to move in an x-direction. For example, in the embodiment illustrated in FIG. 1, an x-axis actuator 123 causes bridge girder 122 to move in the x-direction, for example by one or more drive wheels included in one or both end trucks 124 of bridge girder 122. Thus, x-axis actuator 123 can cause deposition head 130 to follow a programmed motion in the x-direction. Deposition head 130 is movably coupled to bridge girder 122, and a y-axis actuator 125 causes deposition head 130 move in the y-direction along bridge girder 122, for example by drive wheels included in a trolley 127 of deposition head 130. Therefore, y-axis actuator 125 can cause deposition head 130 to follow a programmed motion in the y-direction. Thus, together x-axis actuator 123 and y-axis actuator 125 cause deposition head 130 to precisely follow programmed deposition path 104 on surface 102. Thus, runway beams 121 and bridge girder 122 form a motion platform for moving deposition head 130 along programmed deposition paths on surface 102 of substrate 103.

In the embodiment illustrated in FIG. 1, computer-controlled conductor-deposition machine 100 is configured to cause deposition head 130 to follow a programmed deposition path 104 that varies on surface 102 in the x-direction and the y-direction. In other embodiments, computer-controlled conductor-deposition machine 100 is configured to cause deposition head 130 to follow a programmed deposition path 104 that varies in three orthogonal directions. For example, in such embodiments, programmed deposition path 104 can vary in the x-direction, the y-direction, and the z-direction (which in FIG. 1 is into and out of the page). In such embodiments, computer-controlled conductor-deposition machine 100 further includes a z-axis actuator 126, which may be included in or coupled to deposition head 130. Thus, in such embodiments, computer-controlled conductor-deposition machine 100 can deposit conductive wires 101 onto substrate 102 when curved or otherwise non-planar.

In the embodiment illustrated in FIG. 1, computer-controlled conductor-deposition machine 100 is configured to cause deposition head 130 to follow a programmed deposition path 104 via two or more Cartesian actuators. In other embodiments, computer-controlled conductor-deposition machine 100 is configured with one or more polar axis actuators. For example, in one such embodiment, deposition head 130 is movably coupled to trolley 127 via a wrist (not shown) or one or more other rotatable joints. Thus, in such embodiments, positioning of deposition head 130 relative to substrate 103 is not limited to Cartesian displacements and can include rotation about one or more axes.

The actuators included in computer-controlled conductor-deposition machine 100, such as x-axis actuator 123, y-axis actuator 125, z-axis actuator 126, and a rotatable wrist, can be configured as any suitable actuator for positioning deposition head 130. Examples of suitable actuators include, without limitation, stepper motors, servos, linear actuators, and/or the like.

Controller 150 is configured to move deposition head 130 in a movement pattern relative to the substrate 103, such as along programmed deposition path 104, for example via x-axis actuator 123 and y-axis actuator 125 (and in some embodiments via z-axis actuator 126 and/or one or more polar axis actuators). In various embodiments, controller 150 includes a processor and a memory (not shown) that stores a program that, when executed by the processor, causes controller 150 to move deposition head 130 along programmed deposition path 104. The processor can include any suitable processor, such as a central processing unit (CPU), a graphics processing unit (GPU), an application-specific integrated circuit (ASIC), a field programmable gate array (FPGA), a digital signal processor (DSP), and/or any other type of processing unit, or a combination of different processing units, such as a CPU configured to operate in conjunction with a GPU. In general, the processor can be any technically feasible hardware unit capable of processing data and/or executing software applications. The memory can include a random-access memory (RAM) module, a flash memory unit, or any other type of memory unit or combination thereof. The processor can be configured to read data from and write data to the memory. The memory includes various software programs (e.g., an operating system, one or more applications, and the like) that can be executed by the processor and application data associated with the software programs.

In various embodiments, controller 150 moves deposition head 130 in various movement patterns over substrate 103. For example (and without limitation), the movement pattern can include one or more lines, one or more curves, one or more grids, or the like. The movement pattern can be based on a schematic of circuitry of an electrical and/or electronic device. The movement pattern can include one conductive layer or a plurality of conductive layers (e.g., at different heights relative to the substrate 103). The movement pattern can be a two-dimensional movement pattern or a three-dimensional movement pattern. The movement pattern can be based on a size, shape, position, orientation, and/or curvature of one or more surfaces of substrate 103.

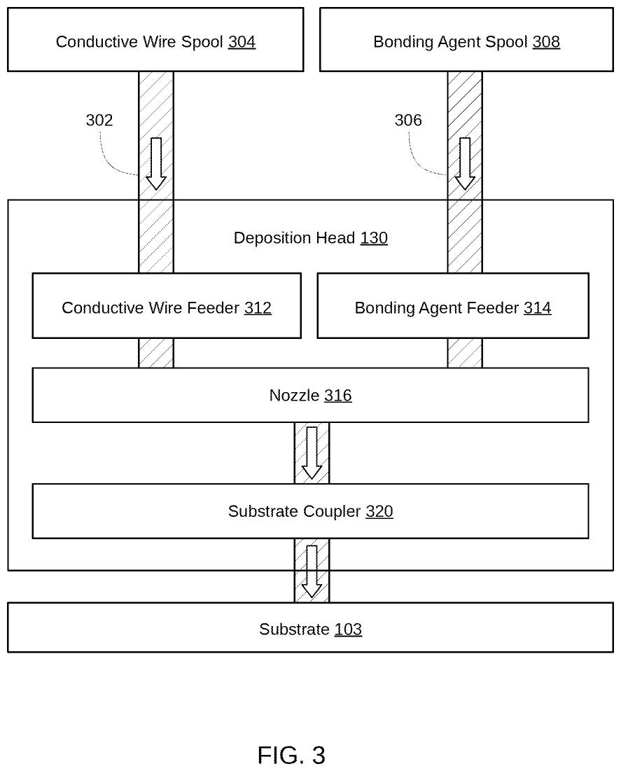

Deposition head 130 enables the deposition of complex conductive wiring systems on surface 102 of substrate 103. Various embodiments of deposition head 130 are described below in conjunction with FIGS. 3-5.

FIG. 3 is a more detailed illustration of deposition head 130, according to various embodiments. In the embodiment illustrated in FIG. 3, a conductive wire spool 304 and a bonding agent spool 308 are disposed proximate deposition head 130. For example, in such embodiments, conductive wire spool 304 and bonding agent spool 308 can be mounted on trolley 127 (shown in FIG. 1) along with deposition head 130. In other embodiments, multiple conductive wire spools 304 and bonding agent spools 308 are disposed proximate deposition head 130, so that deposition head 130 can deposit multiple conductive wires on substrate 103. In yet other embodiments, conductive wire spool(s) 304 and bonding agent spool(s) 308 are included in deposition head 130. In the embodiment illustrated in FIG. 3, deposition head 130 includes a conductive wire feeder 312, a bonding agent feeder 314, a nozzle 316, and a substrate coupler 320.

Conductive wire spool 304 includes a supply of a conductive wire 302. In various embodiments, the conductive wire 302 includes one or more conductive materials, such as (without limitation) copper, zinc oxide, tin, silver, gold, carbon-based materials such as carbon nanotubes or graphene, or the like. In other embodiments (not shown), computer-controlled conductor-deposition machine 100 includes two or more conductive wire spools 304 that each includes a supply of conductive wire 302. In various embodiments, conductive wires 302 are arranged in a pattern, such as a conductive wire net provided by a conductive wire net spool. In various embodiments, different conductive wire spools 304 include the same or similar types of conductive wires 302 or different types of conductive wires 302.

Bonding agent spool 308 includes a supply of a bonding agent 306. In various embodiments, bonding agent 306 includes one or more electrically insulative materials, such as (without limitation) a bonding polymer, a bonding film, an electrically insulative adhesive, or/or the like. In other embodiments (not shown), computer-controlled conductor-deposition machine 100 includes two or more bonding agent spools 308 that each includes a supply of a bonding agent 306. In various embodiments, different bonding agent spools 308 include the same or similar types of bonding agents 306 or different types of bonding agents 306.

Nozzle 316 of deposition head 130 receives conductive wire 302 and bonding agent 306. In some embodiments, nozzle 316 receives both conductive wire 302 and bonding agent 306. In other embodiments, deposition head 130 includes a first nozzle that receives conductive wire 302 and a second nozzle that receives bonding agent 306. In yet other embodiments, nozzle 316 receives two or more conductive wires 302 and/or two or more bonding agents 306. In some embodiments, nozzle 316 includes a cutting device, such as an ultrasonic cutter or a mechanical cutter, for severing conductive wires 302 and/or bonding agents 306 upon completing deposition of a conductive wire on substrate 103.

As shown, deposition head 130 includes conductive wire feeder 312, which feeds conductive wire 302 into nozzle 316. In various embodiments, conductive wire feeder 312 includes one or more extruder motors. As shown, deposition head 130 includes bonding agent feeder 314, which feeds bonding agent 306 into nozzle 316. In various embodiments, bonding agent feeder 314 includes one or more extruder motors. As shown, conductive wire feeder 312 and bonding agent feeder 314 are included in the deposition head 130. In other embodiments (not shown), conductive wire feeder 312 and bonding agent feeder 314 are external to the deposition head 130. In some embodiments (not shown), computer-controlled conductor-deposition machine 100 includes a plurality of deposition heads 130.

Nozzle 316 is configured to deposit the at least one conductive wire 302 and the at least one bonding agent 306 onto substrate 103. In various embodiments, nozzle 103 deposits conductive wire 302 and bonding agent 306 onto substrate 103 concurrently and/or consecutively. In some embodiments, nozzle 316 deposits conductive wire 302 onto substrate 103 and then deposits bonding agent 306 on top of conductive wire 302, as shown in FIG. 3. In this way, conductive wire 302 is positioned in contact with substrate 103, and can act as a charge collector that is insulated from electrical contact with external objects. In other embodiments, nozzle 316 deposits a first layer of bonding agent 306 onto substrate 103, then deposits conductive wire 302 onto the first layer of bonding agent 306, and then deposits a second layer of bonding agent 306 onto conductive wire 302 and the first layer of bonding agent 306. In this way, a fully insulated conductor can be deposited on substrate 103.

Substrate coupler 320 bonds bonding agent 306 and/or the conductive wire 302 to the substrate 103. In various embodiments (not shown), substrate coupler 320 heats substrate 103, conductive wire 302, and/or bonding agent 306, such as (without limitation) via a gas torch, a laser, or an infrared lamp. In various embodiments (not shown), substrate coupler 320 presses conductive wire 302 and/or bonding agent 306 against substrate 103, such as (without limitation) via a compaction roller. In the embodiment shown in FIG. 3, substrate coupler 320 is included in deposition head 330. In other embodiments (not shown), substrate coupler 320 is external to deposition head 130.

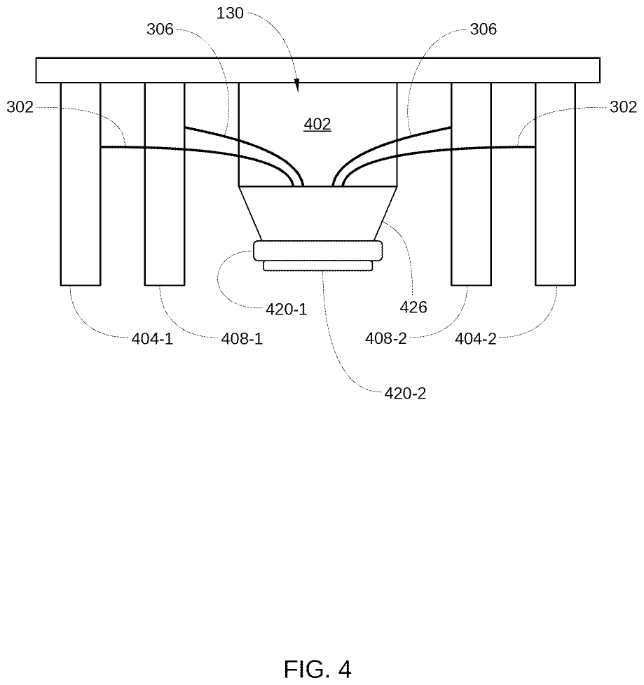

FIG. 4 is another more detailed illustration of deposition head 130, according to various embodiments. As shown, deposition head 130 is positioned proximate two conductive wire spools 404-1, 404-2 and two bonding agent spools 408-1, 408-2 and includes two substrate couplers 420-1, 420-2 and a gantry coupling 402. In the embodiment illustrated in FIG. 4, deposition head 130 can deposit multiple conductive wires (such as conductive wires 101 in FIG. 1) onto a substrate. In such embodiments, multiple conductive wires are deposited along a programmed deposition path.

As shown, each of the two conductive wire spools 404-1, 404-2 includes a supply of conductive wire 302 that is fed into deposition head 130. Similarly, each of the two bonding agent spools 408-1, 408-2 includes a supply of bonding agent 306 that is fed into deposition head 130.

In the embodiment illustrated in FIG. 4, deposition head 130 is coupled to gantry coupling 402, which can be mounted to trolley 127 in FIG. 1 or any other technically feasible device for positioning deposition head 130. In various embodiments (not shown), deposition head 130 is rotatably coupled to gantry coupling by at least one rotatable joint, such as wrist 426. In such embodiments, the at least one rotatable joint can change an orientation of deposition head 130 (and/or gantry coupling 402) with respect to one or more rotational axes, such as (without limitation) a pitch axis, a yaw axis, and/or a roll axis.

In the embodiment illustrated in FIG. 4, deposition head 130 includes first substrate coupler 420-1, such as a heating element that heats conductive wire 102, bonding agent 106, and/or substrate 103. Deposition head 130 further includes second substrate coupler 420-2, such as a compaction roller that presses conductive wire 302 and/or bonding agent 306 against a substrate.

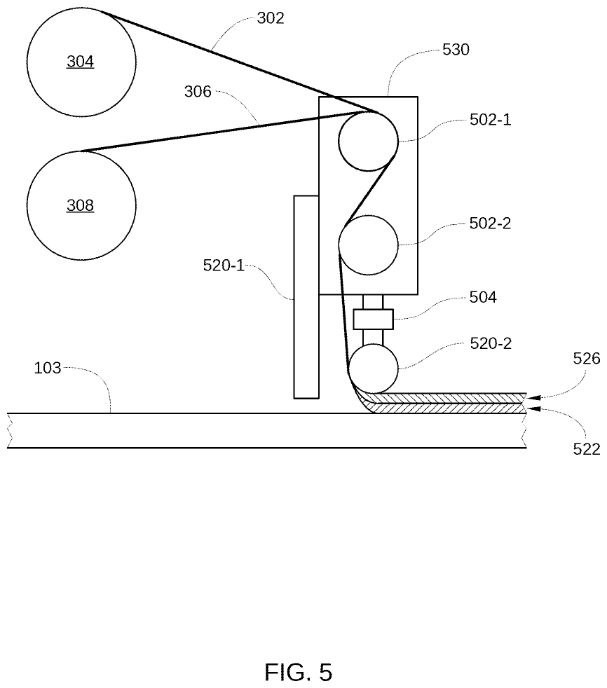

FIG. 5 is another more detailed illustration of a deposition head 530, according to various embodiments. As shown, deposition head 530 is positioned proximate conductive wire spool 304 and bonding agent spool 308, and includes a force sensor 504, two substrate couplers 520-1, 520-2, and two guides 502-1, 502-2. Conductive wire spool 304 includes a supply of conductive wire 302 that is fed into deposition head 530, and bonding agent spool 308 includes a supply of bonding agent 306 that is fed into deposition head 530. In some embodiments, deposition head 530 deposits conductive wire 302 and bonding agent 306 onto substrate 103 concurrently and/or consecutively, so that conductor 522 is formed on substrate 103 and bonding material 526 is formed on top of conductor 522, as shown in FIG. 5.

Each of guides 502-1, 502-2 includes a roller that receives conductive wire 302 and bonding agent 306 and guides conductive wire 302 and bonding agent 306 to another portion of deposition head 530. Guides 502-1, 502-2 can act as a wire tensioner device that applies tension to conductive wire 302 and bonding agent 306 during operation. For example (and without limitation), in some embodiments, second guide 502-2 can pull the length of conductive wire 302 and/or bonding agent 306 received from the first guide 502-1 taut. Deposition head 530 includes a nozzle (not shown in FIG. 5) that extrudes conductive wire 302 and bonding agent 306 from deposition head 530 toward substrate 103, thus causing conductive wire 302 and bonding agent 306 to be deposited on substrate 103.

Substrate couplers 520-1, 520-2 bond conductive wire 302 and bonding agent 306 to substrate 103. In the embodiment illustrated in FIG. 5, substrate coupler 520-1 includes a heating element that heats conductive wire 302, bonding agent 306, and substrate 103. In addition, substrate coupler 520-2 includes a compaction roller that presses conductive wire 302 and bonding agent 306 against substrate 103. In various embodiments, substrate coupler 520-1 includes at least one of a gas torch, a laser, an infrared lamp, or the like.

Force sensor 504 is coupled to deposition head 130 and measures a force exerted by deposition head 110 against substrate 130. As shown, force sensor 504 couples deposition head 130 to substrate coupler 520-1 and measures a downward force of deposition head 130 toward substrate coupler 520-1 and/or an upward force of substrate coupler 520-1 toward deposition head 130. The force detected by force sensor 504 can indicate contact between substrate coupler 520-1 and substrate 103. Alternatively or additionally, in some embodiments, the force detected by force sensor 504 can indicate a magnitude of pressure applied by substrate coupler 520-1 to conductive wire 302, bonding agent 306, and/or substrate 130. Alternatively or additionally, in some embodiments, force sensor 504 detects torque applied to substrate coupler 520-1 by conductive wire 302 and/or bonding agent 306. In such embodiments, the magnitude of the detected torque can indicate a tension applied to conductive wire 302 and bonding agent 306 during operation.

In various embodiments, controller 150 (shown in FIG. 1) receives a signal indicating the force and/or torque detected by force sensor 504. In response, controller 150 can vary a speed at which deposition head 130 is moved along a programmed deposition path on substrate 103 based on the signal. For example, in some embodiments, controller 150 varies such a speed to increase, maintain, and/or decrease a tensile force exerted on conductive wire 302 and/or bonding agent 306. In such embodiments, controller 150 can prevent too much tension from being applied to conductive wire 302 and/or bonding agent 306 while being deposited, which can otherwise cause conductive wire 302 and/or bonding agent 306 to delaminate or otherwise separate from substrate 103. Further, in such embodiments, controller 150 can prevent too little tension from being applied to conductive wire 302 and/or bonding agent 306 while being deposited, which can otherwise cause portions of conductive wire 302 and/or bonding agent 306 to bridge, wrinkle, or otherwise fail to contact substrate 103.

### Deposition of Wires Directly on Substrate

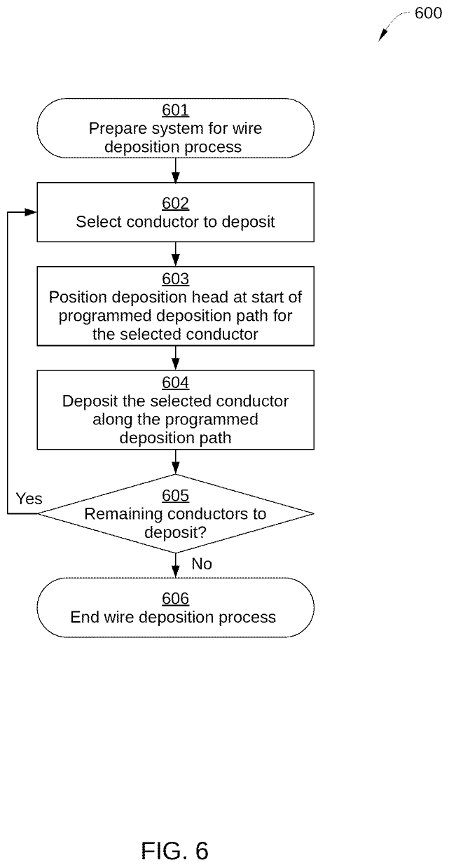

FIG. 6 sets forth a flowchart of method steps for depositing wire when manufacturing a wired product, according to various embodiments. For example, in some embodiments, in the method steps of FIG. 6 an embodiment of computer-controlled conductor-deposition machine 100 is employed to deposit conductive wires directly on a substrate, such as a surface of a solar cell. Although the method steps are described in conjunction with the systems of FIGS. 1-5, persons skilled in the art will understand that any system configured to perform the method steps, in any order, is within the scope of the embodiments.

As shown, a computer-implemented method 600 begins at step 601, where computer-controlled conductor-deposition machine 100 is prepared for deposition of one or more conductive wires 101 on substrate 103. In some embodiments, conductive wire 302 is loaded on conductive wire spool(s) 304 and bonding agent 306 is loaded on bonding agent spool(s) 308. In addition, the conductive wire(s) 304 and bonding agent(s) 306 are fed into deposition head 130, and deposition head 130 is positioned over a substrate 103 that is loaded on computer-controlled conductor-deposition machine 100. In some embodiments, substrate 103 is preheated while loaded on computer-controlled conductor-deposition machine 100.

In step 602, controller 150 selects a specific conductive wire 101 to be deposited on substrate 103. In step 603, controller 150 positions deposition head 130 at the start of a programmed deposition path 104 for the conductive wire 101 to be deposited.

In step 604, controller 150 causes deposition head 130 to deposit the selected conductive wire 101 to be deposited along the programmed deposition path 104. Specifically, controller 150 moves deposition head 130 along the programmed deposition path 104 while depositing conductive wire 101. In embodiments in which conductive wire 101 is a charge collector, deposition head 130 forms conductor 522 on substrate 103 and forms bonding material 526 on top of conductor 522, as shown in FIG. 5.

In some embodiments, as part of the wire deposition process, controller 150 causes the heat-generating device included in deposition head 130 (e.g., substrate coupler 520-1) to heat surface 102 of substrate 103 immediately prior to conductive wire 302 and bonding agent 306 being pressed against substrate 103. In some embodiments, controller 150 causes the heat-generating device included in deposition head 130 to heat surface 102 of substrate 103 to a temperature that is less than the glass-transition temperature of bonding agent 306. In this way, bonding agent 306 does not reach glass-transition temperature and therefore does not become brittle and subject to fracturing and failure. Alternatively or additionally, in some embodiments, controller 150 causes the heat-generating device included in deposition head 130 to heat conductive wire 302 and/or bonding agent 306 to a temperature that is less than the glass-transition temperature of bonding agent 306.

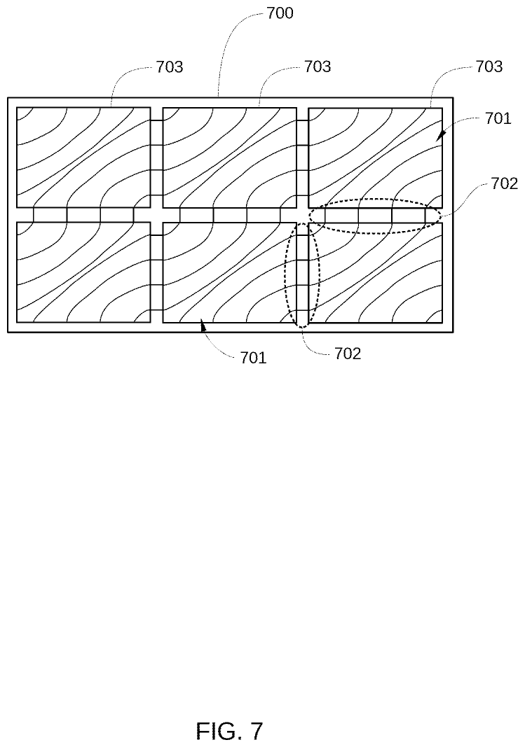

When deposition head 130 reaches the end of programmed deposition path 104, deposition head 130 stops deposition of conductive wire 101 and severs conductive wires 302 and/or bonding agents 306. In some embodiments, substrate 103 includes a single electronic device or component, such as a single PV solar cell. In such embodiments, programmed deposition paths 104 generally provides a layout of conductive wires 101 for a wiring system within the single electronic device or component. Alternatively, in some embodiments, substrate 103 includes multiple electronic devices or components. In such embodiments, a single programmed deposition path 104 can traverse the multiple electronic devices or components. In such embodiments, one or more programmed deposition paths 104 can provide a layout of conductive wires 101 for a wiring system within the single electronic device or component and/or between the multiple electronic devices or components. One such embodiment is described below in conjunction with FIG. 7.

FIG. 7 schematically illustrates a multi-component substrate 700, according to various embodiments. As shown, multi-component substrate 700 includes a plurality of electronic devices 703 that are interconnected with one or more conductive wires 701. For example, each electronic device 703 can be a PV solar cell. In such embodiments, reliable electrical connections 702 between each electronic device are formed in the same operation that other wiring is deposited on each of the electronic devices 703. Thus, the difficulty of manipulating wires, which can be too delicate for robotic manipulators, can be avoided. Instead, reliable electrical connections can be formed between multiple electronic devices in an array in an automated process.

Returning to FIG. 6, in some embodiments, a multi-layered routing of conductive wires 101 is being formed on substrate 103. In such embodiments, one or more conductive wires 101 are deposited on substrate 103 in a first layer, the additional conductive wires 101 are deposited on substrate 103 in one or more subsequent layers. In such embodiments, conductive wires 101 included in one layer generally cross one or more conductive wires 101 in the other layers. To prevent shorting between such conductive wires 101 that cross each other, in some embodiments, controller 150 reduces heat generated by a heat-generating device included in deposition head 130 (e.g., substrate coupler 520-1) when deposition head 130 crosses a previously deposited conductive wire 101. In this way, bonding material 526 formed on the previously deposited on top of the previously deposited conductive wire is not compromised.

In step 605, controller 150 determines whether there are any remaining conductors to be deposited. If yes, method 600 returns to step 602; if no, method 600 proceeds to step 606 and terminates.

### Deposition of Wires on Flexible Substrate to Form Wired Film

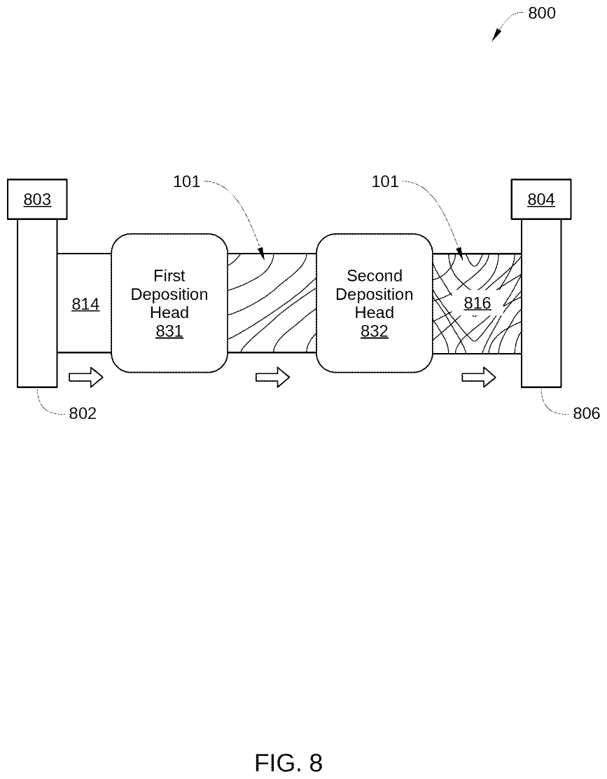

In some embodiments, conductive wires are laid on a thin, flexible substrate, such as a polymeric film, to form a wired film. Patches or segments of the wired film are then applied to an electronic device or component, such as a solar cell, via a press compaction mechanism. One such embodiment is described below in conjunction with FIGS. 8-10.

FIG. 8 schematically illustrates a film-wiring system 800, according to various embodiments. As shown, film-wiring apparatus 800 includes a bonding agent film spool 802, an unspooler 803, a first deposition head 831, a second deposition head 832, a respooler 804, and a wired film spool 806. In some embodiments, first deposition head 831 and second deposition head 832 can be consistent with deposition head 130 of FIG. 1, 3, or 4 or deposition head 530 of FIG. 5.

Bonding agent film spool 802 includes a supply of a bonding agent film 814. In various embodiments, bonding agent film 814 includes one or more electrically insulative materials, such as (without limitation) a bonding polymer, a bonding film, an electrically insulative adhesive, or/or the like. As shown, bonding agent film spool 802 is coupled to unspooler 803, which unspools bonding agent film 814 for processing.

First deposition head 831 deposits conductive wires 101 onto bonding agent film 814 in a first movement pattern. In the embodiment shown in FIG. 8, the first movement pattern of first deposition head 831 includes a lengthwise or longitudinal pattern. Second deposition head 832 deposits conductive wire 101 onto bonding agent film 814 in a second movement pattern. In the embodiment shown in FIG. 8, the movement pattern of second deposition head 832 includes a widthwise or lateral pattern that is generally perpendicular to the first movement pattern. Alternatively, the second movement pattern can be any other suitable pattern of programmed deposition paths. In alternative embodiments, (not shown), a single deposition head deposits conductive wire 101 onto bonding agent film 814 in multiple movement patterns, such as the first movement pattern (e.g., a lengthwise or longitudinal movement pattern) followed by the second movement pattern (e.g., a widthwise or lateral movement pattern). The deposition of conductive wires 101 by first deposition head 831 and second deposition head 832 onto bonding agent film 814 forms a wired film 816.

In some embodiments, a conductive wire 101 is deposited onto bonding agent film 814 by first deposition head 831 or second deposition head 832 by partially melting or otherwise activating a surface of bonding agent film 814. For example, a heat-generating device included in first deposition head 831 or second deposition head 832 can heat bonding agent film 814 to a temperature that is less than a glass-transition temperature of bonding agent film 814. Thus, in such embodiments, a conductive wire can be deposited onto bonding agent film 814 without the use of a bonding agent being provided to first deposition head 831 or second deposition head 832 via a bonding agent spool.

As shown, after deposition of conductive wires 101 onto bonding agent film 814, wired film 816 is collected by wired film spool 806. Wired film spool 806 is coupled to respooler 804, which respools wired film 816. Portions of wired film 816 can be applied to a specific electronic device or component when unspooled from wired film spool 806. Alternatively, in some embodiments, film-wiring apparatus 800 includes a film cutter (not shown) in lieu of wired film spool 806. In some embodiments, the film cutter cuts segments of wired film 816 after deposition of conductive wires 101 onto bonding agent film 814. In some embodiments, the film cutter cuts segments of bonding agent film 814 before deposition of conductive wires 101. In such embodiments, conductive wires 101 are then deposited onto each individual segment of bonding agent film 814 to form segments of wired film 816. In various embodiments, the film cutter includes an ultrasonic cutting array.

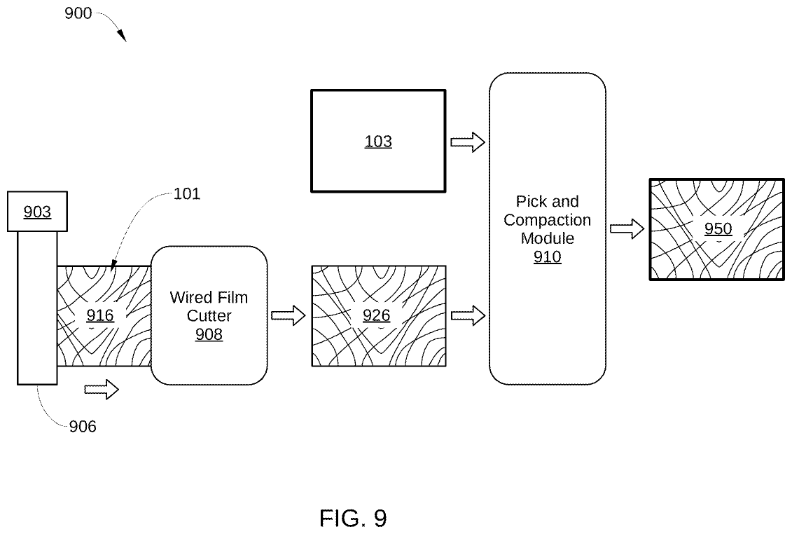

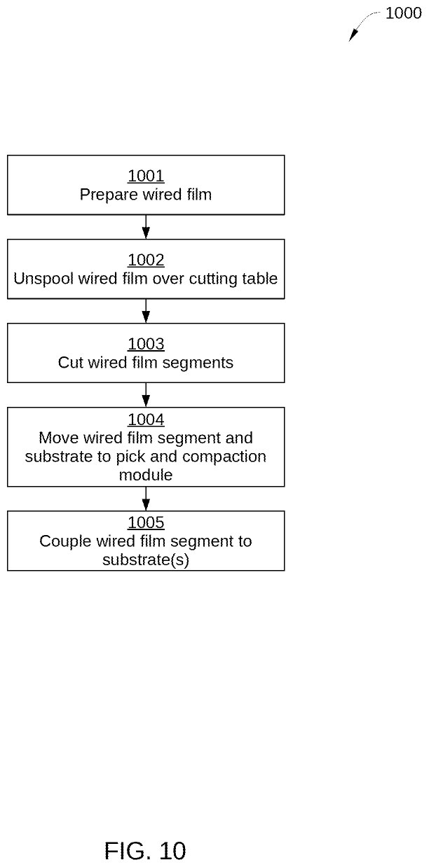

In some embodiments, portions of such a wired film are applied to one or more electronic devices or components in a single application process via a press compaction mechanism. Embodiments of such a press compaction mechanism are described below in conjunction with FIG. 9 and embodiments of such an application process are described below in conjunction with FIG. 10.

FIG. 9 schematically illustrates an electronic device functionalization system 900, according to various embodiments. As shown, electronic device functionalization system 900 includes a wired film spool 906, an unspooler 903, a wired film cutter 908, and a pick and compaction module 910. Wired film spool 906 includes a supply of wired film 916, which can be consistent with wired film 816 of FIG. 8. Unspooler 903 unspools wired film 916, which includes deposited conductive wires 101 laid out in a specific pattern for functionalizing a specific electronic device or component. Wired film cutter 908 cuts wired film 916 into one or more wired film sections 926. In various embodiments, wired film sections 926 can be of a same or similar size and/or shape, or of different sizes and/or shapes. In various embodiments, wired film sections 926 can include conductive wires 101 deposited in a same or similar movement pattern, or conductive wires 101 deposited in different movement patterns. In various embodiments, wired film cutter 908 includes an ultrasonic cutting array.

Pick and compaction module 910 picks a wired film section 926 and bonds wired film section 926 to a suitable substrate 103 to generate a functionalized electronic component 950. In some embodiments, pick and compaction module 910 couples a wired film section 926 to a substrate via a compaction process or a compaction and heating process. In various embodiments, functionalized electronic components 950 can include (without limitation) wired chips, wired circuit boards, wired solar panels, wired construction panels, or the like.

In the embodiment illustrated in FIG. 9, a single wired film section 926 of wired film 916 is coupled to a single substrate 103. In other embodiments, a single wired film section 926 of wired film 916 can be configured and cut to be coupled to multiple substrates 103 in a single compaction and heating process. Thus, in such embodiments, electrical connections between multiple substrates 103 can be implemented via a wiring deposition process as described herein, rather than making individual wiring connections between each substrate 103.

FIG. 10 sets forth a flowchart of method steps for functionalizing an electronic component or electronic device with a wired conductive film, according to various embodiments. Although the method steps are described in conjunction with the systems of FIGS. 1-5, 8 and 9, persons skilled in the art will understand that any system configured to perform the method steps, in any order, is within the scope of the embodiments.

As shown, a computer-implemented method 1000 begins at step 1001, where wired film 906 is prepared. In some embodiments, film-wiring system 800 is employed to prepare wired film 906. For example, in one such embodiment, film-wiring system 800 unspools bonding agent film 814 for processing, engages bonding agent film 814 for processing, and deposits conductive wires 101 onto bonding agent film 814 via first deposition head 831 and second deposition head 832. Film-wiring system 800 then spools wired film 916 onto wired film spool 906.

In step 1002, electronic device functionalization system 900 unspools wired film 916 from wired film spool 906 onto a cutting table or other surface of device functionalization system 900. In step 1003, electronic device functionalization system 900 cuts wired film 916 into wired film sections 926. In step 1004, electronic device functionalization system 900 moves one or more substrates 103 and a wired film section 926 to pick and compaction module 910 for example via one or more conveyor belts or the like. In step 1005, electronic device functionalization system 900 couples the wired film section 926 to the one or more substrates 103, for example via a compaction process or a compaction and heating process.

In sum, the various embodiments described herein provide techniques for functionalizing an electronic device or component with conductive wiring. The herein described techniques enable the precise deposition of conducive wiring onto a two-dimensional or three-dimensional surface of a substrate. In some embodiments the substrate can be an electronic component that includes precisely positioned and/or easily damaged wiring, such as a PV solar cell or array of PV solar cells. In other embodiments, the substrate can be a flexible film, such as a polymeric film. In such embodiments, the flexible film, can subsequently be coupled to a substrate in a single operation to functionalize the substrate with conductive wiring.

At least one technical advantage of the disclosed techniques relative to the prior art is that the disclosed techniques enable the precise and curvilinear deposition of wiring or other conductors on a two- or three-dimensional substrate, such as a photovoltaic solar cell. As a result, conductors on the surface of a photovoltaic solar cell can be positioned in an ideal configuration for charge collection. This reduces ohmic losses and shading of the photovoltaic solar cell, thereby increasing overall efficiency. In addition, less silver and/or other conductive materials is required for charge collection and interconnection of adjacent photovoltaic solar cells. These technical advantages provide one or more technological advancements over prior art approaches.

1. In some embodiments, an apparatus includes: at least one conductive wire spool; a motion platform that includes a first actuator for following a first programmed motion in a first dimension and a second actuator for following a second programmed motion in a second dimension that is perpendicular to the first direction; a deposition head that is mounted to the motion platform, receives a conductive wire from the conductive wire spool, and attaches the conductive wire onto a surface of a substrate; and a controller that causes the motion platform to move along a programmed deposition path on the surface of the substrate, wherein at least a portion of the programmed deposition path varies in the first dimension and in the second dimension.

2. The apparatus of clause 1, wherein the motion platform further includes a third actuator for following a third programmed motion in a third dimension that is perpendicular to both the first direction and the second direction.

3. The apparatus of clauses 1 or 2, wherein at least a portion of the third programmed deposition path varies in the third dimension.

4. The apparatus of any of clauses 1-3, further comprising a feedback sensor that generates a signal indicating a tensile force exerted on the conductive wire while the motion platform moves along the programmed deposition path, and the deposition head receives the conductive wire from the conductive wire spool.

5. The apparatus of any of clauses 1-4, wherein the feedback sensor comprises one of a torque sensor or a force sensor.

6. The apparatus of any of clauses 1-5, wherein the controller further modulates a speed of the motion platform along the programmed deposition path in response to a signal indicating a tensile force exerted on the conductive wire.

7. The apparatus of any of clauses 1-6, wherein the controller further reduces the speed of the motion platform when the signal indicates that the tensile force exerted on the conductive wire exceeds a threshold value.

8. The apparatus of any of clauses 1-7, wherein the signal is generated by a feedback sensor associated with the deposition head.

9. The apparatus of any of clauses 1-8, wherein the controller further modulates a feed rate of conductive wire from the at least one conductive wire spool in response to a signal indicating a tensile force exerted on the conductive wire.

10. The apparatus of any of clauses 1-9, wherein the controller further increases the feed rate of the conductive wire from the at least one conductive wire spool when the signal indicates that the tensile force exerted on the conductive wire exceeds a threshold value.

11. In some embodiments, a computer-implemented method for depositing wire when manufacturing an electrically wired product includes: causing a deposition head to move along a first programmed deposition path on a surface of a substrate, wherein at least a portion of the first programmed deposition path varies in a first dimension and in a second dimension; while the deposition head moves along the first programmed deposition path, attaching at least one conductive wire to the surface of the substrate.

12. The computer-implemented method of clause 11, wherein the substrate comprises one of a photo-voltaic cell or a charge-capture membrane for the photo-voltaic cell.

13. The computer-implemented method of clauses 11 or 12, wherein attaching the at least one conductive wire to the surface of the substrate comprises at least one of heating the surface of the substrate or pressing the at least one conductive wire and at least one bonding agent onto the surface of the substrate.

14. The computer-implemented method of any of clauses 11-13, wherein heating the surface of the substrate comprises heating the surface to a temperature that is less than a glass-transition temperature of the at least one bonding agent.

15. The computer-implemented method of any of clauses 11-14, wherein the at least one bonding agent is received by the deposition head while the deposition head moves along the first programmed deposition path.

16. The computer-implemented method of any of clauses 11-15, wherein attaching the at least one conductive wire to the surface of the substrate comprises simultaneously pressing the at least one conductive wire and at least one bonding agent onto the surface of the substrate.

17. The computer-implemented method of any of clauses 11-16, wherein simultaneously pressing the at least one bonding agent onto the surface of the substrate comprises pressing the at least one bonding agent onto the at least one conductive wire and onto the surface of the substrate.

18. The computer-implemented method of any of clauses 11-17, wherein the at least one conductive wire comprises two or more conductive wires that are received simultaneously by the deposition head while the deposition head moves along the first programmed deposition path.

19. The computer-implemented method of any of clauses 11-18, wherein attaching the two or more conductive wires to the surface of the substrate comprises simultaneously pressing the two or more conductive wires and two or more bonding agents onto the surface of the substrate.

20. The computer-implemented method of any of clauses 11-19, wherein simultaneously pressing the two or more conductive wires and two or more bonding agents onto the surface of the substrate comprises pressing a first of the two or more bonding agents onto a first of the two or more conductive wires and pressing a second of the two or more bonding agents onto a second of the two or more conductive wires.

Any and all combinations of any of the claim elements recited in any of the claims and/or any elements described in this application, in any fashion, fall within the contemplated scope of the present invention and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “module,” a “system,” or a “computer.” In addition, any hardware and/or software technique, process, function, component, engine, module, or system described in the present disclosure may be implemented as a circuit or set of circuits. Furthermore, aspects of the present disclosure may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors may be, without limitation, general purpose processors, special-purpose processors, application-specific processors, or field-programmable gate arrays.

The flowchart and block diagrams in the figures illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the preceding is directed to embodiments of the present disclosure, other and further embodiments of the disclosure may be devised without departing from the basic scope thereof, and the scope thereof is determined by the claims that follow.

What is claimed is:

1. An apparatus, comprising:
at least one conductive wire spool;
a motion platform that includes a first actuator for following a first programmed motion in a first dimension and a second actuator for following a second programmed motion in a second dimension that is perpendicular to the first direction;
a deposition head that is mounted to the motion platform, receives a conductive wire from the conductive wire spool, and attaches the conductive wire onto a surface of a substrate; and
a controller that causes the motion platform to move along a programmed deposition path on the surface of the substrate, wherein at least a portion of the programmed deposition path varies in the first dimension and in the second dimension.

2. The apparatus of claim 1, wherein the motion platform further includes a third actuator for following a third programmed motion in a third dimension that is perpendicular to both the first direction and the second direction.

3. The apparatus of claim 2, wherein at least a portion of the third programmed deposition path varies in the third dimension.

4. The apparatus of claim 1, further comprising a feedback sensor that generates a signal indicating a tensile force exerted on the conductive wire while the motion platform moves along the programmed deposition path, and the deposition head receives the conductive wire from the conductive wire spool.

5. The apparatus of claim 4, wherein the feedback sensor comprises one of a torque sensor or a force sensor.

6. The apparatus of claim 1, wherein the controller further modulates a speed of the motion platform along the programmed deposition path in response to a signal indicating a tensile force exerted on the conductive wire.

7. The apparatus of claim 6, wherein the controller further reduces the speed of the motion platform when the signal indicates that the tensile force exerted on the conductive wire exceeds a threshold value.

8. The apparatus of claim 6, wherein the signal is generated by a feedback sensor associated with the deposition head.

9. The apparatus of claim 1, wherein the controller further modulates a feed rate of conductive wire from the at least one conductive wire spool in response to a signal indicating a tensile force exerted on the conductive wire.

10. The apparatus of claim 9, wherein the controller further increases the feed rate of the conductive wire from the at least one conductive wire spool when the signal indicates that the tensile force exerted on the conductive wire exceeds a threshold value.

11. A computer-implemented method for depositing wire when manufacturing an electrically wired product, the method comprising:
causing a deposition head to move along a first programmed deposition path on a surface of a substrate, wherein at least a portion of the first programmed deposition path varies in a first dimension and in a second dimension;
while the deposition head moves along the first programmed deposition path, attaching at least one conductive wire to the surface of the substrate.

12. The computer-implemented method of claim 11, wherein the substrate comprises one of a photo-voltaic cell or a charge-capture membrane for the photo-voltaic cell.

13. The computer-implemented method of claim 11, wherein attaching the at least one conductive wire to the surface of the substrate comprises at least one of heating the surface of the substrate or pressing the at least one conductive wire and at least one bonding agent onto the surface of the substrate.

14. The computer-implemented method of claim 13, wherein heating the surface of the substrate comprises heating the surface to a temperature that is less than a glass-transition temperature of the at least one bonding agent.

15. The computer-implemented method of claim 13, wherein the at least one bonding agent is received by the deposition head while the deposition head moves along the first programmed deposition path.

16. The computer-implemented method of claim 11, wherein attaching the at least one conductive wire to the surface of the substrate comprises simultaneously pressing the at least one conductive wire and at least one bonding agent onto the surface of the substrate.

17. The computer-implemented method of claim 16, wherein simultaneously pressing the at least one bonding agent onto the surface of the substrate comprises pressing the at least one bonding agent onto the at least one conductive wire and onto the surface of the substrate.

18. The computer-implemented method of claim 11, wherein the at least one conductive wire comprises two or more conductive wires that are received simultaneously by the deposition head while the deposition head moves along the first programmed deposition path.

19. The computer-implemented method of claim 18, wherein attaching the two or more conductive wires to the surface of the substrate comprises simultaneously pressing the two or more conductive wires and two or more bonding agents onto the surface of the substrate.

20. The computer-implemented method of claim 19, wherein simultaneously pressing the two or more conductive wires and two or more bonding agents onto the surface of the substrate comprises pressing a first of the two or more bonding agents onto a first of the two or more conductive wires and pressing a second of the two or more bonding agents onto a second of the two or more conductive wires.
